(19) United States
(12) Patent Application Publication
(10) Pub. No.: US 2006/0152275 A1
(43) Pub. Date: Jul. 13, 2006

(54) Signal transmitting circuit

(75) Inventors: Shou-Kuo Hsu, Tu-Cheng (TW); Jie Zhou, Shenzhen (CN); Xiang Zhu, Shenzhen (CN); Hong-Mei Hu, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/317,359

(22) Filed: Dec. 23, 2005

(30) Foreign Application Priority Data
Jan. 10, 2005 (CN) 200510032793.6

(51) Int. Cl. H01L 25/00

(52) U.S. Cl. 327/565

(57) ABSTRACT

A signal transmitting circuit includes a driving circuit, and a plurality of receiving circuits receiving signals transmitted from the driving circuit. Each of the receiving circuits is coupled to the driving circuit consecutively via a transmission line. A voltage regulator is coupled to the driving circuit and the receiving circuits and provides power to the driving circuit and the receiving circuits. A number of capacitors are coupled between the voltage regulator and the ground for filtering the noise of the power output from the voltage regulator. The capacitors between the voltage regulator and the north bridge chipset filtering the noise of the power output from the voltage regulator maintain signal integrity as the terminal resistor does. It is of advantage that the signal transmitting circuit is simple to manufacture and very suitable for mass production.

### BACKGROUND OF THE INVENTION

1. Field of the Invention

The present invention relates to computer systems, and more particularly to technique of transmitting a signal between elements such as a north bridge chipset and a number of memory slots.

2. Background

Signal integrity is an important factor to be taken into account when a printed circuit board (PCB) is designed. A well-designed PCB has an elevated on-off switching speed of integrated circuits, and a high density, compact layout of components. Parameters of the components and of the PCB substrate, a layout of the components on the PCB, and a layout of high-speed signal transmission lines all have an impact on signal integrity. In turn, proper signal integrity helps the PCB and an associated computer system to achieve stable performance. Impedance matching is considered as an important part of signal integrity. Therefore a characteristic impedance of a transmission line is designed to match an impedance of a load associated with the transmission line. If the characteristic impedance of the transmission line is mismatched with the impedance of the load, signals arriving at a receiving terminal are apt to be partially reflected, causing a waveform of the signals to distort, overshoot, or undershoot. Signals that reflect back and forth along the transmission line causing “ringing”.

Referring to FIG. 3, a diagram illustrating a conventional signal transmitting circuit coupling a north bridge chipset to two memory slots is shown. A north bridge chipset 10 is coupled to a first memory slot 32 and a second memory slot 34 consecutively via a main transmission line 20. The memory slots 32 and 34 are configured for receiving two memory modules. The distance the second slot 34 to the north bridge chipset 10 is longer than the distance the first slot 32 to the north bridge chipset 10. A termination resistor 40 is coupled between the second memory slot 30 and a power source V_{TT} to eliminate signal reflections. A voltage regulator 50 provides power to the north bridge chipset 10, the first memory slot 32, and the second memory slot 34 respectively. However, employing the terminal resistor to depress the signal reflections need a circuit to produce power source V_{TT}, this increases the cost of the manufacture of the printed circuit and makes layout of components in the PCB more compact and difficult.

What is needed, therefore, is a signal transmitting circuit which not only eliminates the signal reflections and maintains signal integrity, but also can be mass produced at a reasonable cost.

### SUMMARY

An exemplary signal transmitting circuit includes a driving circuit, and a plurality of receiving circuits receiving signals transmitted from the driving circuit. Each of the receiving circuits is coupled to the driving circuit consecutively via a transmission line. A voltage regulator is coupled to the driving circuit and the receiving circuits and provides power to the driving circuit and the receiving circuits. A number of capacitors are coupled between the voltage regulator and the ground for filtering the noise of the power output from the voltage regulator.

It is of advantage that the signal transmitting circuit is simple to manufacture and very suitable for mass production.

Other advantages and novel features will become more apparent from the following detailed description of preferred embodiments when taken in conjunction with the accompanying drawings, in which:

### BRIEF DESCRIPTION OF THE DRAWINGS

FIG. 1 is a block diagram of a signal transmitting circuit in accordance with a preferred embodiment of the present invention;

FIG. 2 is a comparative graph showing signal waveforms obtained at a second memory slot using the signal transmitting circuit of FIG. 1 and FIG. 3; and

FIG. 3 is a block diagram of a conventional signal transmitting circuit coupling a north bridge chipset to two memory slots.

### DETAILED DESCRIPTION OF THE EMBODIMENTS

FIG. 1 shows a block diagram of a signal transmitting circuit in accordance with a preferred embodiment of the present invention. The signal transmitting circuit includes a north bridge chipset 100, a transmission line 200, a first memory slot 320, a second memory slot 340, and a voltage regulator 500.

The north bridge chipset 100 is coupled to the first memory slot 320 and the second memory slot 340 consecutively via the transmission line 200. The voltage regulator 500 provides power to the north bridge chipset 100, the first memory slot 320, and the second memory slot 340 respectively. A plurality of capacitors C1, C2, and C3 used as filter means is connected between the voltage regulator 500 and the ground for filtering noise of the power output from the voltage regulator 500.

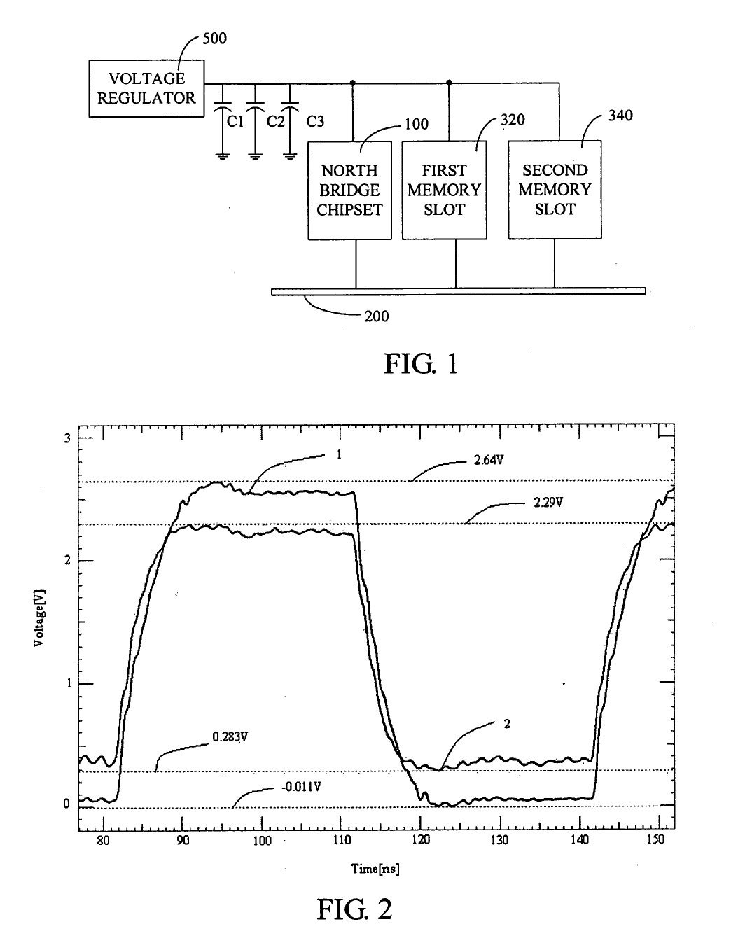

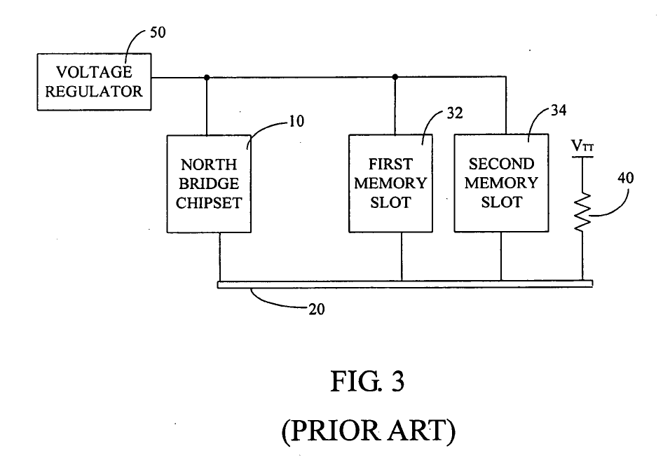

FIG. 2 is a comparative graph showing signal waveforms obtained at the second memory slot using the signal transmitting circuit of FIG. 1 and FIG. 3. Line 1 denotes signal waveform obtained at the second memory slot 34 using the signal transmitting circuit of the FIG. 3, an overshoot voltage is 2.29 volts, and an undershoot voltage is 0.283 volts. Line 2 denotes signal waveform obtained at the second memory slot 340 using the signal transmitting circuit of FIG. 1. The allowable range of the overshoot voltage and the undershoot voltage is from −0.03 volts to 2.9 volts. As shown in FIG. 2, though the amplitude of the waveform of the line 1 is higher than that of the line 2, the amplitude is in the range that the circuit allows. Connecting a number of capacitors C1, C2, and C3 between the voltage regulator 500 and the north bridge chipset 100 to filter the noise of the power output from the voltage regulator 500 maintains signal integrity as the terminal resistor of FIG. 3 does.

In the above-described signal transmitting circuit of the preferred embodiment of the present invention, the capacitors connected to the voltage regulator for filtering the noise are applied to couple the north bridge chipset 100 to two memory slots 320 and 340. Other embodiments with one driving circuit coupling to a plurality of receiving circuits can use the signal transmission circuit with a plurality of capacitors connected to the voltage regulator.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

We claim:

1. A signal transmitting circuit comprising:
a driving circuit;
a plurality of receiving circuits receiving signals transmitted from the driving circuit, each of the receiving circuits coupled to the driving circuit consecutively via a transmission line;
a voltage regulator coupled to the driving circuit and the receiving circuits and providing power to the driving circuit and the receiving circuits; and
at least one capacitor coupled between the voltage regulator and the ground for filtering the noise of the power output from the voltage regulator.

2. The signal transmitting circuit as claimed in claim 1, wherein the driving circuit is a north bridge chipset.

3. The signal transmitting circuit as claimed in claim 1, wherein the plurality of receiving circuits comprises two memory slots.

4. A layout method within a printed circuit board (PCB) comprising the steps of:
setting a driving circuit and a plurality of receiving circuits on the PCB;
coupling the driving circuit to the receiving circuits via a transmission line;
setting a voltage regulator on the PCB for providing power to the driving circuit and the receiving circuits; and
coupling a plurality of capacitors between the voltage regulator and the ground for filtering noise of the power output from the voltage regulator.

5. The layout method as claimed in claim 4, wherein the driving circuit is a north bridge chipset.

6. The layout method as claimed in claim 4, wherein the plurality of receiving circuits comprises two memory slots.

7. A method for circuit arrangement, comprising the steps of:
electrically connecting a driving circuit and a plurality of receiving circuits so as to provide signal transmission between said driving circuit and said plurality of receiving circuits;
powering said driving circuit and said plurality of receiving circuits respectively via at least one power source for activation of said signal transmission thereof; and
electrically connecting at least one filter means between said at least one power source and said circuits including said driving circuit and said plurality of receiving circuits so as to filter power from said at least one power source before said power enters said driving circuit and said plurality of receiving circuits.

8. The method as claimed in claim 7, wherein said filter means comprises a plurality of capacitors electrically connectable in a parallel manner.
